(19) United States
(12) Patent Application Publication
(10) Pub. No.: US 2023/0054236 A1
(43) Pub. Date: Feb. 23, 2023

(54) DAMAGE-PREVENTION FASTENING TOOL FOR MANUFACTURING

(71) Applicant: KYNDRYL, INC., NEW YORK, NY (US)

(72) Inventors: Cesar Augusto Rodriguez Bravo, Heredia (CR); Carolina Garcia Delgado, Zapopan (MX); Desilda Toska, Alajuela (CR); Narayana Aditya Madineni, Southport (AU)

(21) Appl. No.: 17/445,655

(22) Filed: Aug. 23, 2021

(51) Int. Cl. G09B 19/24; B25B 21/00; H05K 3/30; G02B 27/01

(52) U.S. Cl. CPC G09B 19/24; B25B 21/00; H05K 3/303; G02B 27/0172; G05B 15/02

(57) ABSTRACT

An operator uses a handheld fastening tool to fasten a surface-mount technology printed-circuit board (PCB) to an adjacent object by installing a fastener at a target location on the PCB. The operator wears augmented-reality (AR) eyewear equipped with image-recognition technology. The system identifies the distance between the target location and the nearest electronic component mounted to the PCB. An accelerometer integrated into the fastening tool continuously monitors the inclination of the tool and the frequency of operator hand movements while holding the tool. The distance, inclination, and movement measurements are used to derive a composite score indicating a likelihood that the current fastening task will be completed successfully without damage. The eyewear represents the score to the operator as a color-coded AR object. The measurements, scores, and color coding are continuously updated to give the operator real-time feedback about the operator's current likelihood of success.

### BACKGROUND

The present invention relates in general to quality assurance in manufacturing and in particular to preventing damage to subsystems while being fastened together during an assembly procedure.

### SUMMARY

Embodiments of the present invention comprise systems, methods, and computer program products for a fastening tool that prevents damage to manufactured products during assembly. An operator uses a handheld fastening tool, such as a screwdriver, to fasten a first object, such as a surface-mount technology printed-circuit board (PCB), to an adjacent object. This fastening task is performed by installing a fastener at a target location on the first object, such as by installing a screw into a designated screw hole on a PCB. The operator wears augmented-reality (AR) eyewear equipped with image-recognition technology and the ability to display AR graphics in real time. The system identifies the shortest distance between the target location and any damage-vulnerable component mounted to the first object, such as a surface-mounted integrated circuit installed on a surface-mount PCB. An accelerometer integrated into the fastening tool continuously monitors the current inclination of the handheld tool and the operator's hand movements that occur while the operator holds the tool during the fastening operation. The system uses the distance, inclination, and movement measurements to derive a composite score that is proportional to a likelihood that the current fastening task will be completed without damage to any component of the first object. The eyewear communicates this likelihood to the operator in real time by directing the eyewear to overlay the target location with a color-coded AR object. The continuously varying color of the AR object represents changes in the current likelihood of success, as indicated by the variations in the composite score, that occur in response to the orientation of the tool and to the operator's hand movements. The measurements, scores, and color coding are continuously updated to give the operator real-time feedback about the operator's current likelihood of success.

### BRIEF DESCRIPTION OF THE DRAWINGS

FIG. 1 depicts a cloud computing environment according to an embodiment of the present invention.

FIG. 2 depicts abstraction model layers according to an embodiment of the present invention.

FIG. 3 shows the structure of a computer system and computer program code that may be used to implement a method for a damage-prevention fastening tool for manufacturing in accordance with embodiments of the present invention.

FIG. 4 shows the architecture of a system that may be used to implement a method for a damage-prevention fastening tool for manufacturing in accordance with embodiments of the present invention.

FIG. 5 is a flow chart that illustrates steps of a method for a damage-prevention fastening tool for manufacturing in accordance with embodiments of the present invention.

### DETAILED DESCRIPTION

A manufactured product may be composed of subsystems that are assembled by screwing, riveting, gluing, or otherwise fastening the subsystems into a larger assembly. For example, an electronic device may comprise circuit boards, connectors, and chassis components fastened together with screws, bolts, or rivets; and an article of clothing may comprise pieces of fabric that have been sewn or glued together.

It is possible for a subsystem to be damaged during assembly by a worker with unsteady hands, by a misaligned assembly-line robot, or by other types of manufacturing issues. For example, if a printed circuit board (PCBs) has been populated prior to final assembly, integrated circuits can be damaged by workers who try to screw the board into a chassis with unsteady hands. If a damaged chip has been permanently mounted to the PCB by means of surface-mount technology (SMT), damage to a single chip would ruin the entire board.

This problem is especially troublesome when an assembler uses a handheld mechanical tool, such as an electric screwdriver or handheld rivet gun. Because such devices do not provide the stability of a numerically controlled or rack-mounted screwdriving tool, one slip of the hand can irreparably damage a PCB or other subsystem.

Embodiments of the present invention solve this problem by providing improved handheld manufacturing tools that use an augmented-reality (AR) display to guide operators in real-time. An improved screwdriver or other tool incorporates an accelerometer that allows a computerized control unit to monitor an operator's hand motions. An AR-enabled headset or eyeglasses, worn by the operator, uses image-recognition technology to tell the operator how much skill is needed to perform the current task and to identify an operator's real-time progress in completing the task.

For pedagogical reasons, this application will refer to embodiments of the present invention that comprise the assembly of SMT printed circuit boards with screw-type fasteners. But these references should not be construed to limit embodiments of the present invention to such manufacturing processes. As described above, the present invention's underlying inventive concept is broad enough to encompass other types of manufacturing procedures and products, including processes that involve assembling non-SMT circuit boards, fabrics, and other types of components and rigid or flexible materials, including metals, ceramics, nanomaterials, plastics, and glass. The underlying inventive concept is also broad enough to encompass embodiments directed to other types of fastening mechanisms, such as nailing, riveting, gluing, welding, brazing, and pressure-fitting.

It is to be understood that although this disclosure includes a detailed description on cloud computing, implementation of the teachings recited herein are not limited to a cloud computing environment. Rather, embodiments of the present invention are capable of being implemented in conjunction with any other type of computing environment now known or later developed.

Cloud computing is a model of service delivery for enabling convenient, on-demand network access to a shared pool of configurable computing resources (e.g., networks, network bandwidth, servers, processing, memory, storage, applications, virtual machines, and services) that can be rapidly provisioned and released with minimal management effort or interaction with a provider of the service. This cloud model may include at least five characteristics, at least three service models, and at least four deployment models.

Characteristics are as follows:

On-demand self-service: a cloud consumer can unilaterally provision computing capabilities, such as server time and network storage, as needed automatically without requiring human interaction with the service's provider.

Broad network access: capabilities are available over a network and accessed through standard mechanisms that promote use by heterogeneous thin or thick client platforms (e.g., mobile phones, laptops, and PDAs).

Resource pooling: the provider's computing resources are pooled to serve multiple consumers using a multi-tenant model, with different physical and virtual resources dynamically assigned and reassigned according to demand. There is a sense of location independence in that the consumer generally has no control or knowledge over the exact location of the provided resources but may be able to specify location at a higher level of abstraction (e.g., country, state, or datacenter).

Rapid elasticity: capabilities can be rapidly and elastically provisioned, in some cases automatically, to quickly scale out and rapidly released to quickly scale in. To the consumer, the capabilities available for provisioning often appear to be unlimited and can be purchased in any quantity at any time.

Measured service: cloud systems automatically control and optimize resource use by leveraging a metering capability at some level of abstraction appropriate to the type of service (e.g., storage, processing, bandwidth, and active user accounts). Resource usage can be monitored, controlled, and reported, providing transparency for both the provider and consumer of the utilized service.

Service Models are as follows:

Software as a Service (SaaS): the capability provided to the consumer is to use the provider's applications running on a cloud infrastructure. The applications are accessible from various client devices through a thin client interface such as a web browser (e.g., web-based e-mail). The consumer does not manage or control the underlying cloud infrastructure including network, servers, operating systems, storage, or even individual application capabilities, with the possible exception of limited user-specific application configuration settings.

Platform as a Service (PaaS): the capability provided to the consumer is to deploy onto the cloud infrastructure consumer-created or acquired applications created using programming languages and tools supported by the provider. The consumer does not manage or control the underlying cloud infrastructure including networks, servers, operating systems, or storage, but has control over the deployed applications and possibly application hosting environment configurations.

Infrastructure as a Service (IaaS): the capability provided to the consumer is to provision processing, storage, networks, and other fundamental computing resources where the consumer is able to deploy and run arbitrary software, which can include operating systems and applications. The consumer does not manage or control the underlying cloud infrastructure but has control over operating systems, storage, deployed applications, and possibly limited control of select networking components (e.g., host firewalls).

Deployment Models are as follows:

Private cloud: the cloud infrastructure is operated solely for an organization. It may be managed by the organization or a third party and may exist on-premises or off-premises.

Community cloud: the cloud infrastructure is shared by several organizations and supports a specific community that has shared concerns (e.g., mission, security requirements, policy, and compliance considerations). It may be managed by the organizations or a third party and may exist on-premises or off-premises.

Public cloud: the cloud infrastructure is made available to the general public or a large industry group and is owned by an organization selling cloud services.

Hybrid cloud: the cloud infrastructure is a composition of two or more clouds (private, community, or public) that remain unique entities but are bound together by standardized or proprietary technology that enables data and application portability (e.g., cloud bursting for load-balancing between clouds).

A cloud computing environment is service oriented with a focus on statelessness, low coupling, modularity, and semantic interoperability. At the heart of cloud computing is an infrastructure that includes a network of interconnected nodes.

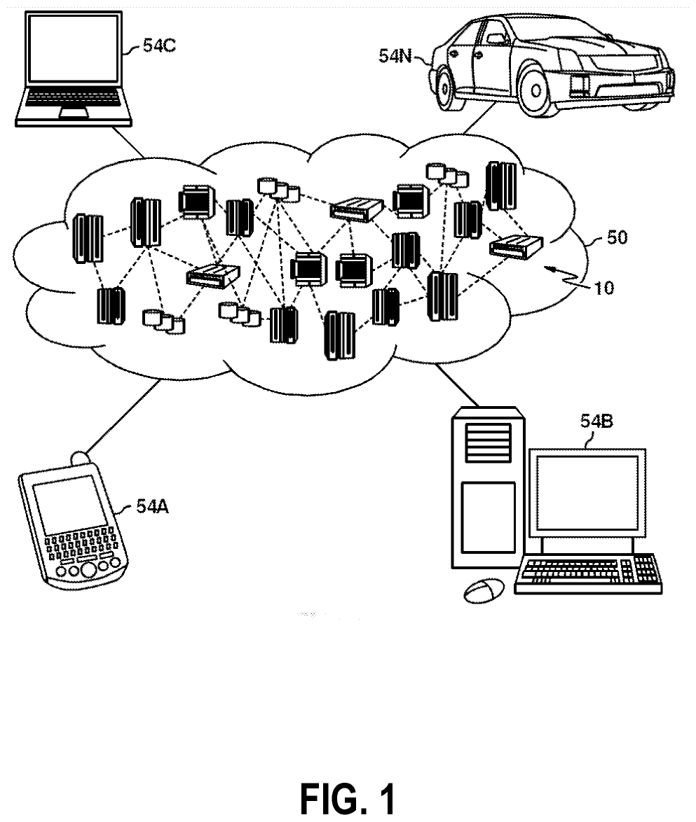

Referring now to FIG. 1, illustrative cloud computing environment 50 is depicted. As shown, cloud computing environment 50 includes one or more cloud computing nodes 10 with which local computing devices used by cloud consumers, such as, for example, personal digital assistant (PDA) or cellular telephone 54A, desktop computer 54B, laptop computer 54C, and/or automobile computer system 54N may communicate. Nodes 10 may communicate with one another. They may be grouped (not shown) physically or virtually, in one or more networks, such as Private, Community, Public, or Hybrid clouds as described hereinabove, or a combination thereof. This allows cloud computing environment 50 to offer infrastructure, platforms and/or software as services for which a cloud consumer does not need to maintain resources on a local computing device. It is understood that the types of computing devices 54A-N shown in FIG. 1 are intended to be illustrative only and that computing nodes 10 and cloud computing environment 50 can communicate with any type of computerized device over any type of network and/or network addressable connection (e.g., using a web browser).

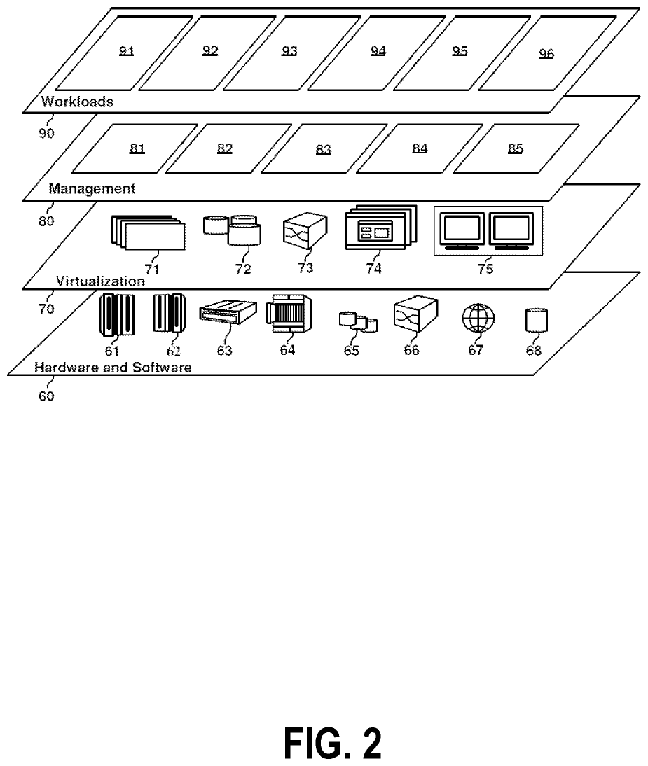

Referring now to FIG. 2, a set of functional abstraction layers provided by cloud computing environment 50 (FIG. 1) is shown. It should be understood in advance that the components, layers, and functions shown in FIG. 2 are intended to be illustrative only and embodiments of the invention are not limited thereto. As depicted, the following layers and corresponding functions are provided:

Hardware and software layer 60 includes hardware and software components. Examples of hardware components include: mainframes 61; RISC (Reduced Instruction Set Computer) architecture based servers 62; servers 63; blade servers 64; storage devices 65; and networks and networking components 66. In some embodiments, software components include network application server software 67 and database software 68.

Virtualization layer 70 provides an abstraction layer from which the following examples of virtual entities may be provided: virtual servers 71; virtual storage 72; virtual networks 73, including virtual private networks; virtual applications and operating systems 74; and virtual clients 75.

In one example, management layer 80 may provide the functions described below. Resource provisioning 81 provides dynamic procurement of computing resources and other resources that are utilized to perform tasks within the cloud computing environment. Metering and Pricing 82 provide cost tracking as resources are utilized within the cloud computing environment, and billing or invoicing for consumption of these resources. In one example, these resources may include application software licenses. Security provides identity verification for cloud consumers and tasks, as well as protection for data and other resources. User portal 83 provides access to the cloud computing environment for consumers and system administrators. Service level management 84 provides cloud computing resource allocation and management such that required service levels are met. Service Level Agreement (SLA) planning and fulfillment 85 provide pre-arrangement for, and procurement of, cloud computing resources for which a future requirement is anticipated in accordance with an SLA.

Workloads layer 90 provides examples of functionality for which the cloud computing environment may be utilized. Examples of workloads and functions which may be provided from this layer include: mapping and navigation 91; software development and lifecycle management 92; virtual classroom education delivery 93; data analytics processing 94; transaction processing 95; and damage-prevention fastening tool for manufacturing 96.

The present invention may be a system, a method, and/or a computer program product at any possible technical detail level of integration. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be accomplished as one step, executed concurrently, substantially concurrently, in a partially or wholly temporally overlapping manner, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

While it is understood that the process software for a damage-prevention fastening tool for manufacturing may be deployed by manually loading it directly in the client, server, and proxy computers via loading a storage medium such as a CD, DVD, etc., the process software may also be automatically or semi-automatically deployed into a computer system by sending the process software to a central server or a group of central servers. The process software is then downloaded into the client computers that will execute the process software. Alternatively, the process software is sent directly to the client system via e-mail. The process software is then either detached to a directory or loaded into a directory by executing a set of program instructions that detaches the process software into a directory. Another alternative is to send the process software directly to a directory on the client computer hard drive. When there are proxy servers, the process will select the proxy server code, determine on which computers to place the proxy servers' code, transmit the proxy server code, and then install the proxy server code on the proxy computer. The process software will be transmitted to the proxy server, and then it will be stored on the proxy server.

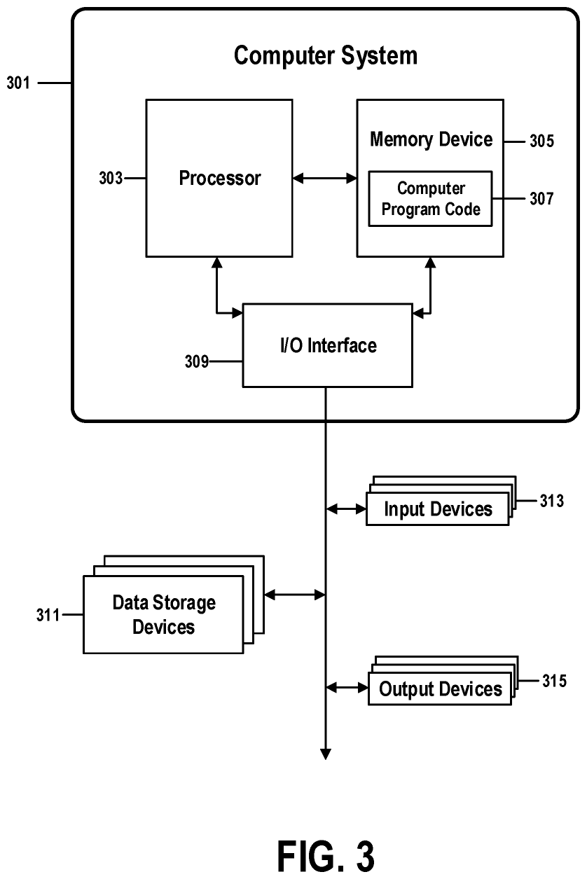

FIG. 3 shows a structure of a computer system and computer program code that may be used to implement a method for a damage-prevention fastening tool for manufacturing in accordance with embodiments of the present invention. FIG. 3 refers to objects 301-315.

In FIG. 3, computer system 301 comprises a processor 303 coupled through one or more I/O Interfaces 309 to one or more hardware data storage devices 311 and one or more I/O devices 313 and 315.

Hardware data storage devices 311 may include, but are not limited to, magnetic tape drives, fixed or removable hard disks, optical discs, storage-equipped mobile devices, and solid-state random-access or read-only storage devices. I/O devices may comprise, but are not limited to: input devices 313, such as keyboards, scanners, handheld telecommunications devices, touch-sensitive displays, tablets, biometric readers, joysticks, trackballs, or computer mice; and output devices 315, which may comprise, but are not limited to printers, plotters, tablets, mobile telephones, displays, or sound-producing devices. Data storage devices 311, input devices 313, and output devices 315 may be located either locally or at remote sites from which they are connected to I/O Interface 309 through a network interface.

Processor 303 may also be connected to one or more memory devices 305, which may include, but are not limited to, Dynamic RAM (DRAM), Static RAM (SRAM), Programmable Read-Only Memory (PROM), Field-Programmable Gate Arrays (FPGA), Secure Digital memory cards, SIM cards, or other types of memory devices.

At least one memory device 305 contains stored computer program code 307, which is a computer program that comprises computer-executable instructions. The stored computer program code includes a program that implements a method for a damage-prevention fastening tool for manufacturing in accordance with embodiments of the present invention, and may implement other embodiments described in this specification, including the methods illustrated in FIGS. 1-5. The data storage devices 311 may store the computer program code 307. Computer program code 307 stored in the storage devices 311 is configured to be executed by processor 303 via the memory devices 305. Processor 303 executes the stored computer program code 307.

In some embodiments, rather than being stored and accessed from a hard drive, optical disc or other writable, rewritable, or removable hardware data-storage device 311, stored computer program code 307 may be stored on a static, nonremovable, read-only storage medium such as a Read-Only Memory (ROM) device 305, or may be accessed by processor 303 directly from such a static, nonremovable, read-only medium 305. Similarly, in some embodiments, stored computer program code 307 may be stored as computer-readable firmware, or may be accessed by processor 303 directly from such firmware, rather than from a more dynamic or removable hardware data-storage device 311, such as a hard drive or optical disc.

Thus the present invention discloses a process for supporting computer infrastructure, integrating, hosting, maintaining, and deploying computer-readable code into the computer system 301, wherein the code in combination with the computer system 301 is capable of performing a method for a damage-prevention fastening tool for manufacturing.

Any of the components of the present invention could be created, integrated, hosted, maintained, deployed, managed, serviced, supported, etc. by a service provider who offers to facilitate a method for a damage-prevention fastening tool for manufacturing. Thus the present invention discloses a process for deploying or integrating computing infrastructure, comprising integrating computer-readable code into the computer system 301, wherein the code in combination with the computer system 301 is capable of performing a method for a damage-prevention fastening tool for manufacturing.

One or more data storage devices 311 (or one or more additional memory devices not shown in FIG. 3) may be used as a computer-readable hardware storage device having a computer-readable program embodied therein and/or having other data stored therein, wherein the computer-readable program comprises stored computer program code 307. Generally, a computer program product (or, alternatively, an article of manufacture) of computer system 301 may comprise the computer-readable hardware storage device.

In embodiments that comprise components of a networked computing infrastructure, a cloud-computing environment, a client-server architecture, or other types of distributed platforms, functionality of the present invention may be implemented solely on a client or user device, may be implemented solely on a remote server or as a service of a cloud-computing platform, or may be split between local and remote components.

While it is understood that program code 307 for a method for a damage-prevention fastening tool for manufacturing may be deployed by manually loading the program code 307 directly into client, server, and proxy computers (not shown) by loading the program code 307 into a computer-readable storage medium (e.g., computer data storage device 311), program code 307 may also be automatically or semi-automatically deployed into computer system 301 by sending program code 307 to a central server (e.g., computer system 301) or to a group of central servers. Program code 307 may then be downloaded into client computers (not shown) that will execute program code 307.

Alternatively, program code 307 may be sent directly to the client computer via e-mail. Program code 307 may then either be detached to a directory on the client computer or loaded into a directory on the client computer by an e-mail option that selects a program that detaches program code 307 into the directory.

Another alternative is to send program code 307 directly to a directory on the client computer hard drive. If proxy servers are configured, the process selects the proxy server code, determines on which computers to place the proxy servers' code, transmits the proxy server code, and then installs the proxy server code on the proxy computer. Program code 307 is then transmitted to the proxy server and stored on the proxy server.

In one embodiment, program code 307 for a method for a damage-prevention fastening tool for manufacturing is integrated into a client, server and network environment by providing for program code 307 to coexist with software applications (not shown), operating systems (not shown) and network operating systems software (not shown) and then installing program code 307 on the clients and servers in the environment where program code 307 will function.

The first step of the aforementioned integration of code included in program code 307 is to identify any software on the clients and servers, including the network operating system (not shown), where program code 307 will be deployed that are required by program code 307 or that work in conjunction with program code 307. This identified software includes the network operating system, where the network operating system comprises software that enhances a basic operating system by adding networking features. Next, the software applications and version numbers are identified and compared to a list of software applications and correct version numbers that have been tested to work with program code 307. A software application that is missing or that does not match a correct version number is upgraded to the correct version.

A program instruction that passes parameters from program code 307 to a software application is checked to ensure that the instruction's parameter list matches a parameter list required by the program code 307. Conversely, a parameter passed by the software application to program code 307 is checked to ensure that the parameter matches a parameter required by program code 307. The client and server operating systems, including the network operating systems, are identified and compared to a list of operating systems, version numbers, and network software programs that have been tested to work with program code 307. An operating system, version number, or network software program that does not match an entry of the list of tested operating systems and version numbers is upgraded to the listed level on the client computers and upgraded to the listed level on the server computers.

After ensuring that the software, where program code 307 is to be deployed, is at a correct version level that has been tested to work with program code 307, the integration is completed by installing program code 307 on the clients and servers.

Embodiments of the present invention may be implemented as a method performed by a processor of a computer system, as a computer program product, as a computer system, or as a processor-performed process or service for supporting computer infrastructure.

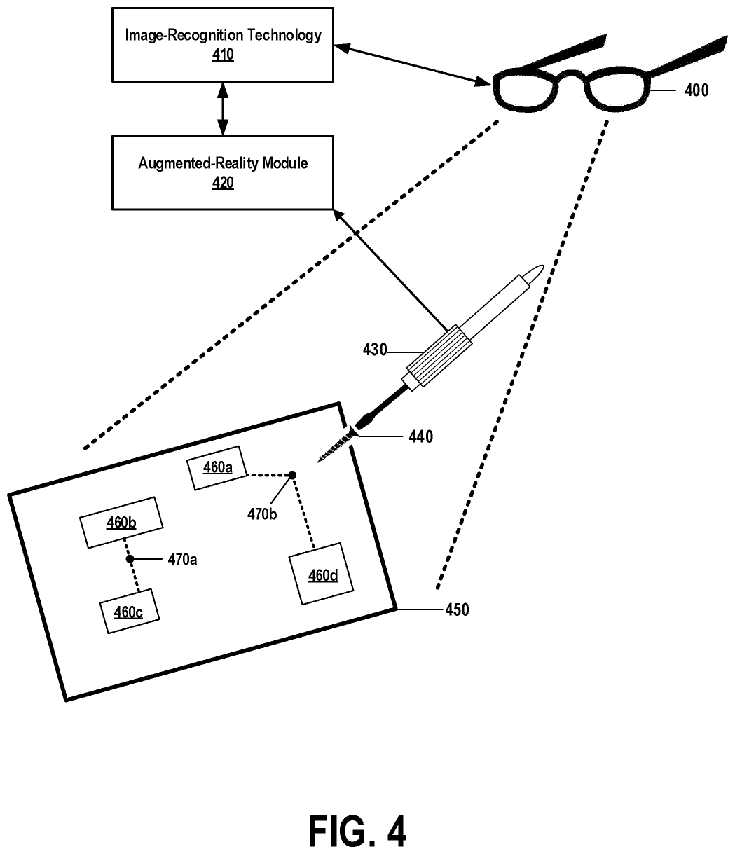

FIG. 4 shows the architecture of a system that may be used to implement a method for a damage-prevention fastening tool for manufacturing in accordance with embodiments of the present invention. FIG. 4 shows items 400-470b.

FIG. 4 shows elements of the current invention as they would be configured while helping a human operator fasten a printed circuit board (PCB) 450 to other subsystems by inserting a screw fastener 440 into a screw hole 470a or 470b on PCB 450. In the figure, PCB 450 is populated with four surface-mounted integrated circuits 460a-460d, and is configured with two screw holes 470a and 470b, into which fasteners like screw 440 can be inserted.

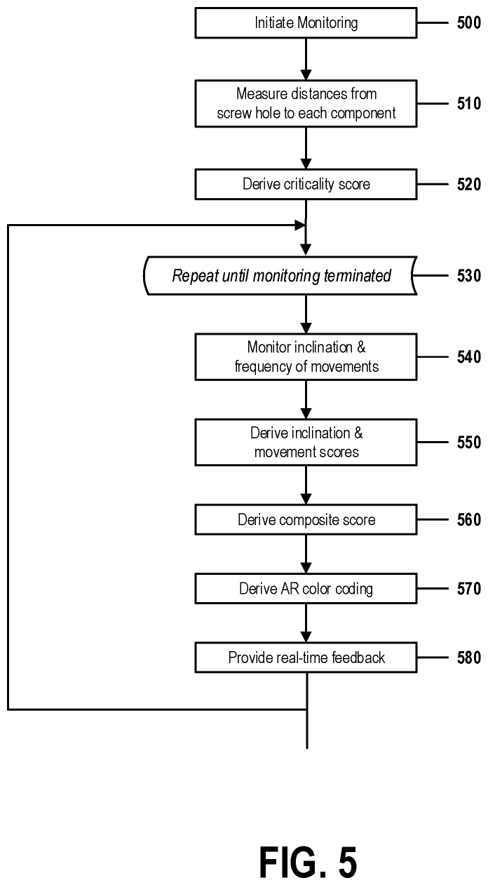

The distances between each screw hole 470a-470b and the closest surface-mounted circuits 460a-460d are shown as dotted lines in FIG. 4. The system identifies and compares these distances during the initial steps of the procedure of FIG. 5 in order to determine a degree of difficulty and a degree of precision associated with inserting a screw 440 into a corresponding screw hole 470a or 470b. For example, the distance between screw hole 470a and circuit 460b is less than the distance between screw hole 470b and any circuit 460a-460d. The system would thus associate a greater degree of difficulty with the task of inserting screw 440 into hole 470a than to the task of inserting screw 440 into hole 470b.

A human operator wears eyewear 400 or a headset 400 that incorporates embedded image-recognition technology 410 or that communicates with an outboard image-recognition module 410. This image-recognition technology 410 allows eyewear 400 to visually monitor the operator's progress while the operator attempts to use a handheld electric screwdriver 430 to insert screw fastener 440 into a fastening hole 470a or 470b.

Augmented-reality module 420 receives real-time motion information from an accelerometer or other motion-detecting technology embedded into handheld screwdriver 430. This motion information allows the system to monitor the operator's hand motions during a fastening procedure.

Using visual information received from eyewear 400 and the motion-detection information received from the screwdriver or other fastening device 430, image-recognition function 410 and augmented-reality module 420 determine the human operator's current degree of progress completing the fastening operation. The augmented-reality module 420 displays a continuously varying AR graphic to a human operator, via eyewear 400, that tells the in real time whether the fastening task is being completed safely.

The image-recognition 410 and augmented-reality 420 elements, regardless of their physical location or form factor, work together and in conjunction with other known types of computerized logic components to continuously monitor the operator's hand motions and to interactively give the operator real-time visual feedback about the operator's progress.

The embodiment shown in FIG. 4 illustrates a manufacturing procedure that involves affixing an SMT PCB 450 to other components by means of screw fasteners 440. But this should not be construed to limit embodiments of the present invention to these precise types of tasks. The present invention is flexible enough to accommodate embodiments that use any sort of fastening mechanism to fasten any sort of components together. Examples of such tasks include riveting or welding sections of sheet metal, gluing together pieces of fabric or ceramic, or soldering wires to terminals.

Similarly, other embodiments may apply the concepts of FIGS. 4 and 5 to non-fastening tasks in order to solve manufacturing problems similar to those described above. Such tasks include cutting panels with a handheld laser or water saw or exposing an area of a photosensitive surface to a beam of light.

Furthermore, although the embodiment of FIG. 4 addresses a manufacturing process in which a human operator performs a monitored task, this should not be construed to limit embodiments of the present invention to human operators. The present invention is flexible enough to accommodate embodiments in which a manufacturing task is performed by a numerical-control device, robot, or other automated mechanism that is vulnerable to errors that can result in damage to a component or subassembly.

In this latter case, FIG. 4's eyewear 400 and augmented-reality functionality 420 would be replaced in a straightforward manner by computerized functions that transmit analogous information to the automated mechanism. This analogous information may or may not be visual in nature, but if it is visual, the information would be forwarded electronically to a component of the automated mechanism capable of understanding the meaning of the visual information and reacting in real time to a continuous receipt of the visual information

FIG. 5 is a flow chart that illustrates steps of a method for a damage-prevention fastening tool for manufacturing in accordance with embodiments of the present invention. FIG. 5 shows steps 500-580, which may be performed by embodiments analogous to those shown in FIGS. 1-4.

As in FIG. 4, although FIG. 5 describes a procedure by which human operators use screw fasteners 440 to fasten SMT PCBs 450 to other assemblies, the present invention is flexible enough to accommodate other types of embodiments, including those enumerated at the conclusion of the description of FIG. 4.

In step 500, the procedure of FIG. 5 is initiated through any means known in the art and preferred by an implementer. For example, the procedure could be manually initiated by turning on eyewear 400 or by pressing a button on fastening device 430, or could be initiated automatically upon the detection of a visual cue by eyewear 400. For example, the procedure of FIG. 5 could be initiated when the system detects that a previous iteration of the procedure has been completed, either by a successful fastening operation or by a determination that the previous fastening operation has failed. In another example, an electric screwdriver 400 could initiate the procedure when a human operator presses a button on the screwdriver 400 or shakes the screwdriver 400 in a certain way that can be identified by an accelerometer integrated into the screwdriver 400.

This initiation enables the system, through means known in the art, to identify the next fastening operation to be completed. This identification includes determining the type of fastener 440 to be used, the screw hole 470a-470b or other target location associated with the fastener 440, and other parameters and factors associated with this current task.

In step 510, the system determines the shortest distance between the current screw hole (in this example, the current screw hole is arbitrarily deemed to be hole 470b of FIG. 4) and any other component of interest on PCB 450. In the example of FIG. 4, this shortest distance is the distance between hole 470b and surface-mounted device 460a.

Distance determinations may be made by any means known in the art. For example, the system could infer distances by referring to a previously generated digital image of the layout of PCB 450. In other cases, the system could refer to other previously loaded data items, such as a spreadsheet or configuration file that provides information from which distances can be derived. The system could also determine distances by referring to an image of PCB 450 generated by the image-recognition technology 410 incorporated into eyewear 400.

In some embodiments, the system in this step enumerates the distances between the current screw hole 470b and all other nearby components mounted to PCB 450. In such cases, a component is deemed to be “nearby” if the distance between the component and the current screw hole 470b does not exceed a predetermined threshold that is identified through any means preferred by an implementer.

In step 520, a “criticality” or “degree of difficulty” score is derived from the distance measurements derived in step 510. This score may be derived by a procedure as simple as identifying and optionally normalizing a number that is inversely proportional to the shortest distance between the current screw hole 470b and the closest component 460a. If desired by an implementer, more complex derivation methods may be employed. For example, a hole that is 4 mm from a single component could, if desired, be assigned a lower score than a hole that is 4 mm from each of three components or that is 5 mm from each of six components.

Regardless of derivation method, at the conclusion of step 520, the system will have derived a criticality score that is proportional to the degree of difficulty of the current task of installing the current fastener 440. This score may be weighted or otherwise adjusted as a function of whether the operator is a human worker, a robot, or another type of automated manufacturing device.

Step 530 begins an iterative procedure of steps 530-580. This procedure repeats continuously, or periodically at a rate that simulates real-time interactivity, until the system determines that the current fastening procedure has either failed or completed successfully or until the procedure is terminated through other means. These means include operations that are the inverse of those described in step 500, such as pressing a button on screwdriver 430 or detecting that the operation has completed by visual inspection and analysis performed by image-recognition technology 410.

In step 540, the accelerometer function of screwdriver 430 monitors the instantaneous inclination of screwdriver 430 and the frequency of an operator's hand movements while holding screwdriver 430. In some embodiments, the accelerometer also measures the magnitude of each movement. These measurements are repeated each time through the iterative procedure of steps 530-580 and are transmitted to other computerized components of the system for analysis.

In step 550, the system uses the measurements received in step 540 to generate, or to update previously generated, inclination and movement scores. The inclination score is derived as a function of the current degree of inclination of screwdriver 430, compared to a predetermined standard inclination. For example, the system might in this step determine how closely screwdriver 430 is to a perpendicular drawn vertically from the surface of PCB 450, or to the vertical axis of screw hole 470b. If screwdriver 430 is perpendicular to the surface of PCB 450 or is properly aligned to insert screw 440 into screw hole 470b, then the inclination score would indicate a readiness to complete the current fastening task. However, if an inclination of screwdriver 440 indicates a 37° tilt, relative to the true perpendicular, then the system would determine that the operator cannot at this point insert screw 440 into hole 470b.

The inclination of screwdriver 430 can also indicate other factors that affect the likelihood that the current fastening task is ready to be completed. For example, a predetermined assembly procedure could mandate that a fastening tool 430 be rotated along certain axes in order to access a hard-to-reach target location 470b. The present invention is flexible enough to accommodate embodiments that comprise any sort of considerations deemed relevant by an implementer, when deriving an inclination score. But in all cases, the value of the inclination score is proportional (or inversely proportional) to the desirability of the inclination measured in step 540.

Similarly, the system in this step uses the measurements received in step 540 to generate or update a movement score. The movement score is derived as a function of the frequency of movements of screwdriver 430 (that is, the number of movements recorded during a predetermined period of time). These movements may be recorded during a measurement period that extends through a duration of time during one iteration of the procedure of steps 530-580; may be derived as a function of movements recorded over multiple iterations of the procedure of steps 530-580; or as some combination thereof.

These movements may be used to indicate any condition, specified by an implementer, that indicates a relative likelihood that the operator is ready to complete the current fastening task, or a relative likelihood that the operator is capable of completing the current fastening task. For example, rapid, lower-amplitude movements could indicate that the operator has unsteady hands. If the magnitude of these movements approaches a predetermined fraction of the shortest distance, as measured in step 510, the system could infer a critical condition in which the operator could not with confidence be trusted to complete the fastening task. In another example, repeated large gestures could be inferred to indicate that the operator is unsure of the best way to approach the target screw hole 460a.

The present invention is flexible enough to accommodate any inferences, predetermined thresholds, or other considerations that an implementer deems relevant to determining whether an operator's hand movements indicate a greater or lesser likelihood that the current fastening task will be completed successfully. In all cases, however, a value of the resulting movement score should be proportional (or, if desired by an implementer, inversely proportional) to a likelihood that the current task will be successfully completed.

In step 560, the system derives a composite score that is proportional to an overall likelihood that the current fastening task will be successfully completed. This derivation is based on the most recent measurement of the inclination of screwdriver 430; the number, frequency, and magnitude of an operator's hand movements; the distance between the target screw hole 470b and one or more components 460a-460d on PCB 450; or a combination thereof.

The composite score is derived from the most recent values of the criticality, inclination and movement scores, and like those three component scores, is updated with each iteration of the procedure of steps 530-580. In certain embodiments, the procedure of steps 530-580 is repeated so rapidly that the composite score is, or appears to be, updated continuously, in real time, or quickly enough to allow an operator to associate the operator's hand movements with the updated feedback presented in step 580.

The derivation of the composite score may comprise any computations preferred by an implementer that associates current values of the three component scores (generated in the most recent iteration of steps 520 and 550) with a relative likelihood of successful completion of the current fastening task. The present invention is flexible enough to accommodate any sort of computations deemed relevant by an implementer. These computations may include scaling or normalization of the component scores or the composite score, weightings assigned to each component score, consideration of context-dependent factors; and any other type of mathematical or statistical calculations known in the art. In a simple example, a composite score may be derived as the mere average of the three component scores, either before or after normalization of each component score to a value between 1.00 and 0.00.

In step 570, the system selects a color that best represents the likelihood of success or failure indicated by the composite score derived in step 560. This selection is performed as a function of a previously derived color scheme that maps colors onto ranges of likelihood. For example, a composite-score value derived from measurements indicating that the operator is poised to correctly insert screw 440 into hole 470b might be associated with a green color; a value derived from measurements indicating that the operator is holding screwdriver 430 firmly at an oblique angle to the surface of PCB 450, but in proximity to screw hole 470b might be associated with a yellow color; and a value derived from measurements indicating that the operator is holding screwdriver 440 at an oblique angle with shaky hands, and that screw hole 470b is extremely close to several SMT components of PCB 450 might be associated with a red color.

An implementer may select any type of color scheme that the implementer believes would work best within the context of the implementer's manufacturing process and products. This selection can include, at the implementer's discretion, choices of the total number of colors, the meaning associated with each color, and the ranges of composite-score values associated with each color.

Other types of color-coding schemes may be selected. For example, instead of a set of discrete colors that are each mapped onto a discrete, non-overlapping range of composite-score values, the system may map the range of possible score values onto points in a smooth range of continuously varying colors, with higher values being associated with redder hues and lower values being associated with bluer hues. In other embodiments, other aspects of a color may indicate values of other parameters associated with a likelihood of success. For example, a color's brightness, tint, or saturation may increase with the length of time that the current fastening task has been in progress; or a magenta color may become slightly redder each time that magenta is selected during the same fastening task.

In step 580, the system directs augmented reality module 420 to generate a color-coded AR object and transmit the object to eyewear 400, which overlays the object onto PCB 450. In the example of FIGS. 4 and 5, the AR object could be a color-coded disc or circle centered on the target screw hole 470b. The color, intensity, saturation, hint, or other parameter of this circle would indicate the likelihood of success of the current task. Other embodiments may substitute any other sort of geometric or animated AR graphic, as preferred by an implementer. For example, an embodiment may display a semi-transparent three-dimensional cube that rises, falls, and rotates in response to analogous hand motions or in response to analogous movements of the screwdriver tip.

This display is updated by each iteration of the procedure of steps 530-580. In embodiments capable of quick enough response time, the result will be a real-time, interactive animation that gives the operator immediate visual feedback about the operator's handling of fastening device 430.

In one example, upon clicking a START button on screwdriver 430, an operator may initially see, in eyewear 400, an augmented-reality red disc centered on screw hole 470b. As the operator moves the screwdriver 430 closer to hole 470b, the red disc becomes increasingly orange. When the operator tilts screwdriver 430 to a vertical orientation, relative to the surface of PCB 450, the disc becomes yellow. The operator then positions screwdriver 430 directly over screw hole 470b with a steady hand. When the disc becomes green, the operator lowers screw 440 into the screw hole 470b and turns on the screwdriver to complete the current task.

To the operator's eyes, the AR display is updated in real time, giving the operator the experience of an interactive user interface. Systems that cannot provide real-time response perform similar color-coding and display functionality, but there may be a noticeable lag between an operator hand motion and an update of the AR object's color coding.

In some embodiments, the system performs additional actions, including advisory actions or warnings. For example, if an artificially intelligent component is included in the computerized logic, the system may determine that a human operator requires additional audio or visual guidance or suggestions, including graphical arrow markers to further guide the operator, or a zoom or magnification function that allows the operator to guide fastening tool 430 more precisely. In other embodiments, the system would contact a supervisor or other personnel if the system determines that the operator is experiencing a greater-than-acceptable level of difficulty or has required a greater-than-acceptable length of time to complete the current fastening task.

In as similar manner, if the system determines that an automated fastening mechanism, such as a robotic assembler, is experiencing difficulty completing the current fastening task, certain embodiments would take further steps, such as notifying a technician or supervisor of the problem, and would optionally terminate or pause the current fastening task.

The iterative process of steps 530-550 terminates when the current fastening task is determined to be complete. This determination may be made in response to: an indication by the image-recognition module 410 that the fastener has been successfully inserted; an indication by the image-recognition module 410 that the fastener has failed or must be restarted; the operator's manual manipulation of a thumbwheel, button, or other controller indicating that the user desires the task to be terminated; a completion of an electrical circuit that indicates that PCB 450 has been successfully fastened to an adjacent subsystem; or any other termination-indication mechanism known in the art and desired by an implementer.

Examples and embodiments of the present invention described in this document have been presented for illustrative purposes. They should not be construed to be exhaustive nor to limit embodiments of the present invention to the examples and embodiments described here. Many other modifications and variations of the present invention that do not depart from the scope and spirit of these examples and embodiments will be apparent to those possessed of ordinary skill in the art. The terminology used in this document was chosen to best explain the principles underlying these examples and embodiments, in order to illustrate practical applications and technical improvements of the present invention over known technologies and products, and to enable readers of ordinary skill in the art to better understand the examples and embodiments disclosed here.

What is claimed is:

1. A system comprising a processor, a memory coupled to the processor, and a computer-readable hardware storage medium coupled to the processor, the storage medium containing program code configured to be run by the processor via the memory to implement a method for a damage-prevention fastening tool for manufacturing, the method comprising:
assigning a difficulty score to a fastening task, where the fastening task comprises fastening a printed circuit board (PCB) to another object by using a handheld tool to install a fastener at a fastening location on the PCB, where the difficulty score is a function of a shortest distance between the fastening location and any electronic component mounted to the PCB;
starting a monitoring session that continuously adjusts in real time:
i) a movement score derived as a function of an operator's hand movements while attempting to perform the fastening task,
ii) an inclination score derived as a function of a degree of inclination of the handheld tool relative to a surface of the PCB, and
iii) a composite score, derived by correlating current values of the difficulty, movement, and inclination scores, that indicates the operator's relative chance of successfully completing the fastening task; and
displaying to the operator a continuously updated augmented-reality (AR) graphic that visually identifies the relative chance of success indicated by the composite score.

2. The system of claim 1, where the handheld tool is an electric screwdriver, the fastener is a screw, and the fastening location is a screw hole.

3. The system of claim 1, where the electronic components are mounted to the PCB using surface-mount technology (SMT).

4. The system of claim 1, where the augmented-reality graphic is color-coded to identify the relative chance of success indicated by the most recently derived value of the composite score.

5. The system of claim 1, where the AR graphic is displayed to the user on AR-enabled eyewear worn by the operator.

6. The system of claim 1, where the inclination score and the movement score are continuously adjusted in response to operator hand movements detected in real time by an accelerometer integrated into the handheld tool.

7. The system of claim 1, where the movement score is a function of a frequency of occurrence of the hand movements, magnitudes of the hand movements, or a combination thereof.

8. A method comprising:
a system comprising a processor, a memory coupled to the processor, and a computer-readable hardware storage medium coupled to the processor, the storage medium containing program code configured to be run by the processor via the memory to implement the method for a damage-prevention fastening tool for manufacturing, the method comprising:
assigning a difficulty score to a fastening task, where the fastening task comprises fastening a printed circuit board (PCB) to another object by using a handheld tool to install a fastener at a fastening location on the PCB, where the difficulty score is a function of a shortest distance between the fastening location and any electronic component mounted to the PCB;
starting a monitoring session that continuously adjusts in real time:
i) a movement score derived as a function of an operator's hand movements while attempting to perform the fastening task,
ii) an inclination score derived as a function of a degree of inclination of the handheld tool relative to a surface of the PCB, and
iii) a composite score, derived by correlating current values of the difficulty, movement, and inclination scores, that indicates the operator's relative chance of successfully completing the fastening task; and
displaying to the operator a continuously updated augmented-reality (AR) graphic that uses color coding to visually identify the relative chance of success indicated by the composite score.

9. The method of claim 8, where the handheld tool is an electric screwdriver, the fastener is a screw, and the fastening location is a screw hole.

10. The method of claim 8, where the electronic components are mounted to the PCB using surface-mount technology (SMT).

11. The method of claim 8, where the AR graphic is displayed to the user on AR-enabled eyewear worn by the operator.

12. The method of claim 8, where the inclination score and the movement score are continuously adjusted in response to operator hand movements detected in real time by an accelerometer integrated into the handheld tool.

13. The method of claim 8, where the movement score is a function of a frequency of occurrence of the hand movements, magnitudes of the hand movements, or a combination thereof.

14. The method of claim 8, further comprising providing at least one support service for at least one of creating, integrating, hosting, maintaining, and deploying computer-readable program code in the computer system, wherein the computer-readable program code in combination with the computer system is configured to implement the assigning, the starting a monitoring session, and the displaying.

15. A computer program product comprising a computer readable storage medium having program instructions embodied therewith, the program instructions executable by a processor to cause the processor to perform a method for a damage-prevention fastening tool for manufacturing, the method comprising:
assigning a difficulty score to a fastening task, where the fastening task comprises fastening a printed circuit board (PCB) to another object by using a handheld tool to install a fastener at a fastening location on the PCB, where the difficulty score is a function of a shortest distance between the fastening location and any electronic component mounted to the PCB;
starting a monitoring session that continuously adjusts in real time:
i) a movement score derived as a function of an operator's hand movements while attempting to perform the fastening task,
ii) an inclination score derived as a function of a degree of inclination of the handheld tool relative to a surface of the PCB, and
iii) a composite score, derived by correlating current values of the difficulty, movement, and inclination scores, that indicates the operator's relative chance of successfully completing the fastening task; and
displaying to the operator a continuously updated augmented-reality (AR) graphic that uses color coding to visually identify the relative chance of success indicated by the composite score.

16. The computer program product of claim 15, where the handheld tool is an electric screwdriver, the fastener is a screw, and the fastening location is a screw hole.

17. The computer program product of claim 15, where the electronic components are mounted to the PCB using surface-mount technology (SMT).

18. The computer program product of claim 15, where the AR graphic is displayed to the user on AR-enabled eyewear worn by the operator.

19. The computer program product of claim 15, where the inclination score and the movement score are continuously adjusted in response to operator hand movements detected in real time by an accelerometer integrated into the handheld tool.

20. The computer program product of claim 15, where the movement score is a function of a frequency of occurrence of the hand movements, magnitudes of the hand movements, or a combination thereof.
